(19) United States
(12) Patent Application Publication
(10) Pub. No.: US 2024/0147625 A1
(43) Pub. Date: May 2, 2024

(54) SEMICONDUCTOR STORAGE DEVICE AND INFORMATION PROCESSING SYSTEM

(71) Applicant: Kioxia Corporation, Tokyo (JP)

(72) Inventors: Akinobu HIROTA, Yokohama Kanagawa (JP); Shiro HARASHIMA, Sagamihara Kanagawa (JP)

(73) Assignee: Kioxia Corporation, Tokyo (JP)

(21) Appl. No.: 18/458,261

(22) Filed: Aug. 30, 2023

(30) Foreign Application Priority Data
Nov. 1, 2022 (JP) 2022-175478

(51) Int. Cl. H05K 1/18; H01L 23/32; H01L 23/498; H01L 25/18; H05K 5/02; H10B 80/00

(52) U.S. Cl. CPC H05K 1/182; H01L 23/32; H01L 23/49833; H01L 25/18; H05K 5/026; H10B 80/00; H01L 24/32

(57) ABSTRACT

A semiconductor storage device including a memory device, a first substrate, and a second substrate. The memory device includes chips or chip bonded bodies. The first substrate has a first main surface and a second main surface. The memory device is disposed on the first main surface. The second main surface is a main surface on a side opposite to the first main surface. The second substrate has a hollow portion, a third main surface, a fourth main surface, and a connector portion. The memory device is disposed in the hollow portion. The third main surface contacts the first main surface outside the hollow portion. The fourth main surface is a main surface on a side opposite to the third main surface. The connector portion is disposed at an edge portion outside the hollow portion.

### CROSS-REFERENCE TO RELATED APPLICATION

This application is based upon and claims the benefit of priority from Japanese Patent Application No. 2022-175478, filed Nov. 1, 2022, the entire contents of which are incorporated herein by reference.

### FIELD

Embodiments described herein relate generally to a semiconductor storage device and an information processing system.

### BACKGROUND

In the semiconductor storage device, a memory device may be disposed and mounted on a substrate. In this case, the memory device is desired to be compactly mounted.

### DESCRIPTION OF THE DRAWINGS

FIG. 1 is a perspective view illustrating a configuration of a semiconductor storage device according to a first embodiment.

FIGS. 2A to 2C are cross-sectional views illustrating the configuration of the semiconductor storage device according to the first embodiment.

FIG. 3 is a front view illustrating the configuration of the semiconductor storage device according to the first embodiment.

FIG. 4 is a perspective view illustrating a configuration of a structure in the first embodiment.

FIG. 5 is an exploded perspective view illustrating the configuration of the structure in the first embodiment.

FIG. 6 is a cross-sectional view illustrating a configuration of a memory device in the first embodiment.

FIGS. 7A and 7B are cross-sectional views illustrating a configuration of a memory chip in the first embodiment.

FIGS. 8A to 8C are perspective views illustrating a method for manufacturing the semiconductor storage device according to the first embodiment.

FIGS. 9A and 9B are perspective views illustrating the method for manufacturing the semiconductor storage device according to the first embodiment.

FIG. 10 is a perspective view illustrating a configuration of a semiconductor storage device according to a second embodiment.

FIGS. 11A and 11B are cross-sectional views illustrating the configuration of the semiconductor storage device according to the second embodiment.

FIG. 12 is an exploded perspective view illustrating a configuration of a casing in the second embodiment.

FIGS. 13A and 13B are perspective views illustrating a method for manufacturing the semiconductor storage device according to the second embodiment.

FIG. 14 is a front view illustrating a configuration of a semiconductor storage device according to a third embodiment.

FIG. 15 is a perspective view illustrating a configuration of a structure in the third embodiment.

FIG. 16 is an exploded perspective view illustrating the configuration of the structure in the third embodiment.

FIG. 17 is a perspective view illustrating a configuration of a memory device and a socket in the third embodiment.

FIG. 18 is a cross-sectional view illustrating the configuration of the memory device in the third embodiment.

FIGS. 19A to 19C are perspective views illustrating a method for manufacturing the semiconductor storage device according to the third embodiment.

FIG. 20 is a perspective view illustrating a configuration of a semiconductor storage device according to a fourth embodiment.

FIG. 21 is a cross-sectional view illustrating the configuration of the semiconductor storage device according to the fourth embodiment.

FIGS. 22A to 22C are perspective views illustrating a method for manufacturing the semiconductor storage device according to the fourth embodiment.

FIG. 23 is a perspective view illustrating a configuration of a semiconductor storage device according to a fifth embodiment.

FIG. 24 is a cross-sectional view illustrating the configuration of the semiconductor storage device according to the fifth embodiment.

FIGS. 25A to 25E are perspective views illustrating a method for manufacturing the semiconductor storage device according to the fifth embodiment.

FIG. 26 is a perspective view illustrating a configuration of a structure in a modification of the first to fifth embodiments.

### DETAILED DESCRIPTION

Embodiments provide a semiconductor storage device and an information processing system in which a memory device can be compactly mounted.

In general, according to at least one embodiment, there is provided a semiconductor storage device including a memory device, a first substrate, and a second substrate. The memory device includes chips or chip bonded bodies. The first substrate has a first main surface and a second main surface. The memory device is disposed on the first main surface. The second main surface is a main surface on a side opposite to the first main surface. The second substrate has a hollow portion, a third main surface, a fourth main surface, and a connector portion. The memory device is disposed in the hollow portion. The third main surface contacts the first main surface outside the hollow portion. The fourth main surface is a main surface on a side opposite to the third main surface. The connector portion is disposed at an edge portion outside the hollow portion.

Hereinafter, the semiconductor storage devices according to embodiments will be described in detail with reference to the accompanying drawings. In addition, the present disclosure is not limited by these embodiments.

### First Embodiment

In general, according to at least one embodiment, in a semiconductor storage device, a memory device is disposed and mounted on a substrate, and the semiconductor storage device is devised to allow the memory device to be compactly mounted. The semiconductor storage device is subjected to restrictions of a form factor standard. In the semiconductor storage device, the memory device is mounted in the restrictions of the form factor standard.

A semiconductor storage device 1 is, for example, a solid state drive (SSD), and can be configured according to form factor standards for the SSD. The form factor standards may be 1.8 inch standard, 2.5 inch standard, E3.S standard, E1.S standard, M.2 standard, mSATA standard, U.2 standard, and the like.

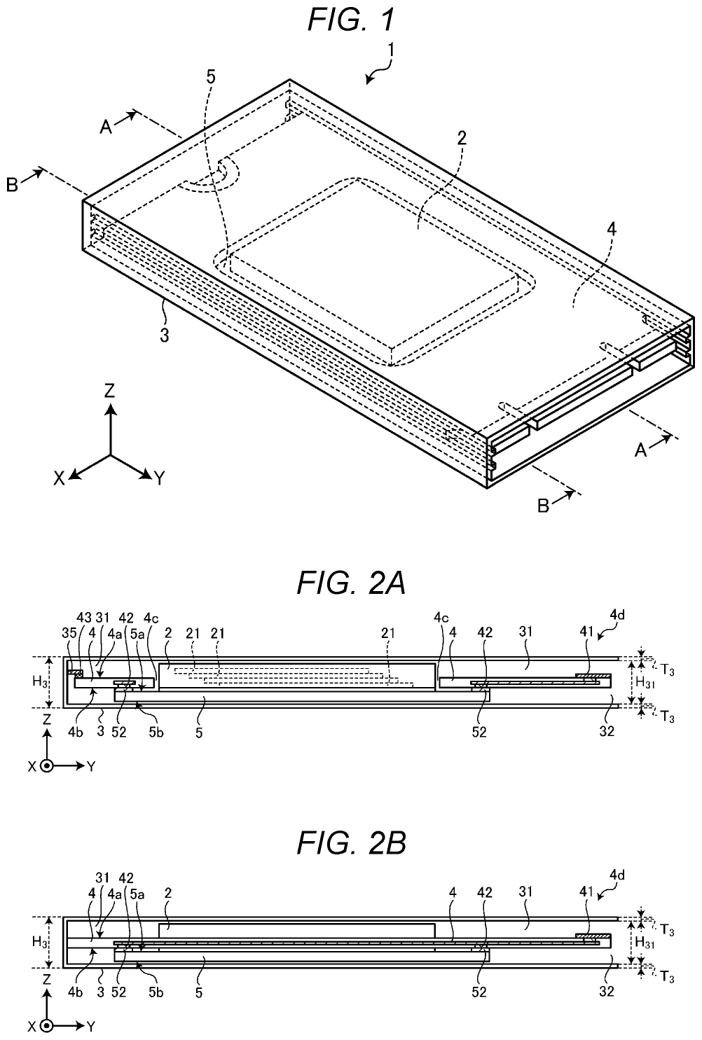

The semiconductor storage device 1 can be configured according to a first form factor standard, as illustrated in FIG. 1. FIG. 1 is a perspective view illustrating a configuration of the semiconductor storage device 1. The first form factor standard is a form factor standard in which the substrate is accommodated in a casing of the semiconductor storage device itself, and may be the 2.5 inch standard. Hereinafter, a longitudinal direction of the memory device is a Y direction, a direction perpendicular to a main surface of the memory device is a Z direction, and a direction perpendicular to the Y and Z directions is an X direction.

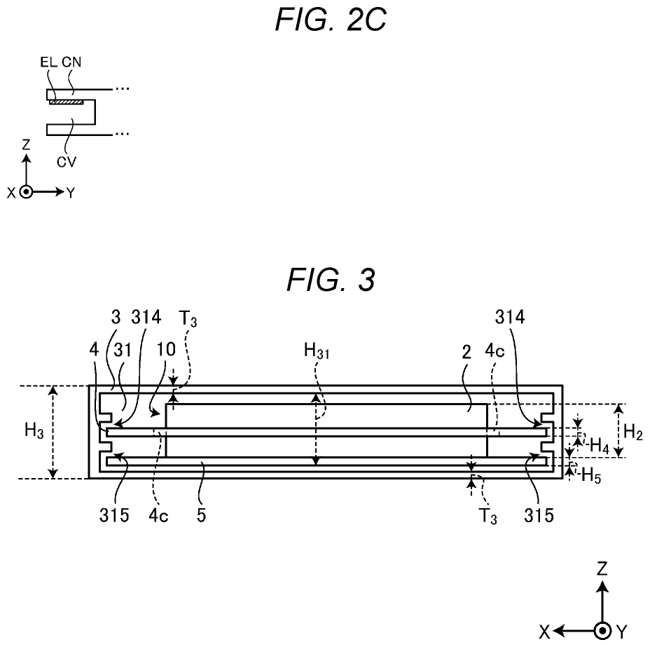

The semiconductor storage device 1 includes a memory device 2, a base substrate 5, a perforated substrate 4, and a casing 3. The memory device 2, the base substrate 5, and the perforated substrate 4 illustrated in FIG. 1 are accommodated in the casing 3, as illustrated in FIGS. 2A, 2B, and 3.

FIGS. 2A to 2C are YZ cross-sectional views illustrating the configuration of the semiconductor storage device 1. FIG. 2A is the YZ cross-sectional view illustrating a configuration of a cross section including the memory device 2 of the semiconductor storage device 1, and illustrates a YZ cross section taken along line A-A of FIG. 1. FIG. 2B is a YZ cross-sectional view illustrating a configuration of a cross section not including the memory device 2 of the semiconductor storage device 1, and illustrates a YZ cross section taken along line B-B of FIG. 1. FIG. 2C is a YZ cross-sectional view illustrating a configuration of a cross section of a connector CN of a host. FIG. 3 is a front view illustrating the configuration of the semiconductor storage device 1, and is a front view of the semiconductor storage device 1 when viewed from a +Y side.

The casing 3 has an opening 32 on the +Y side, and an internal space 31 can be observed from the +Y side. The casing 3 is restricted to have a predetermined height of Hₜₕ or less by being subjected to the height restriction of the first form factor standard. In this case, the casing 3 is configured such that a height H₃ in the Z direction of the casing 3 satisfies Equation 1 below.

H₃≤Hₜₕ Equation 1

The casing 3 has a predetermined thickness T₃ between an outer surface thereof and an inner surface of the internal space 31. A height H₃₁ in the Z direction of the internal space 31 of the casing 3 satisfies Equation 2 below.

H₃₁=H₃−2×T₃≤Hₜₕ−2×T₃ Equation 2

Here, the semiconductor storage device 1 can be electrically connected to the connector CN of the host, and can function as a storage medium for the host. A connection terminal to the host is provided as a connector portion on an outer edge of the substrate according to the first form factor standard. The connector portion can be positioned in the internal space 31. The connector portion is provided on the substrate accommodated near a center in the Z direction in the internal space 31 of the casing 3 for allowing the connector portion to be attached to the connector CN of the host as illustrated in FIG. 2C. The substrate accommodated near the center in the Z direction is tentatively referred to as a substrate 15 (not illustrated).

For example, assume that the memory device 2 is mounted on an upper surface of the substrate 15. Assume that a thickness of the substrate 15 is H₁₅. When a thickness H₂ (see FIG. 3) of the memory device 2 increases, a sum of the thickness H₂ of the memory device 2 and the thickness H₁₅ of the substrate 15 becomes larger than half the height H₃₁ of the internal space 31, as shown in Equation 3 below. For example, there is a possibility that the substrate 15 cannot be accommodated in the internal space 31 with the memory device 2 mounted on the substrate 15 while positioning the substrate 15 near the center in the Z direction in the internal space 31.

H₂+H₁₅>H₃₁/2 Equation 3

When the height H₃ in the Z direction of the casing 3 is equal to the predetermined height Hₜₕ, an expression H₃₁=H₃−2×T₃=Hₜₕ−2×T₃ holds, and thus, when substituting this formula into Equation 3, the following Equation 4 is established.

H₂+H₁₅>Hₜₕ/2−T₃ Equation 4

As shown in Equation 4, there is a possibility that the memory device 2 and the substrate 15 cannot be accommodated in the casing 3 by being subjected to the predetermined height Hₜₕ restriction of the first form factor standard. The substrate 15 serves both as a substrate for connection to the host and as a substrate for mounting the memory device 2.

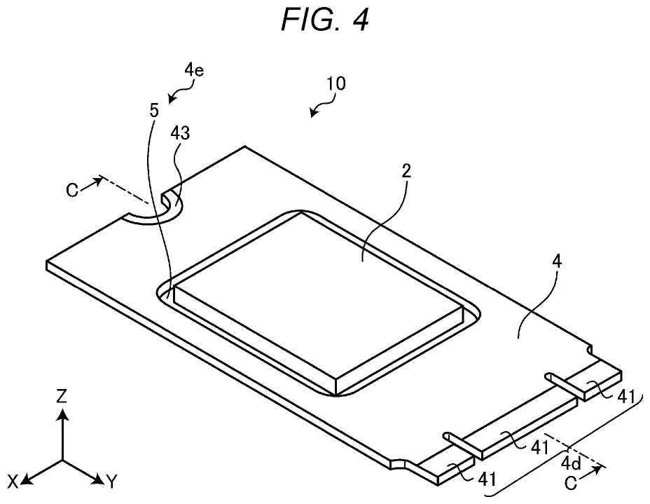

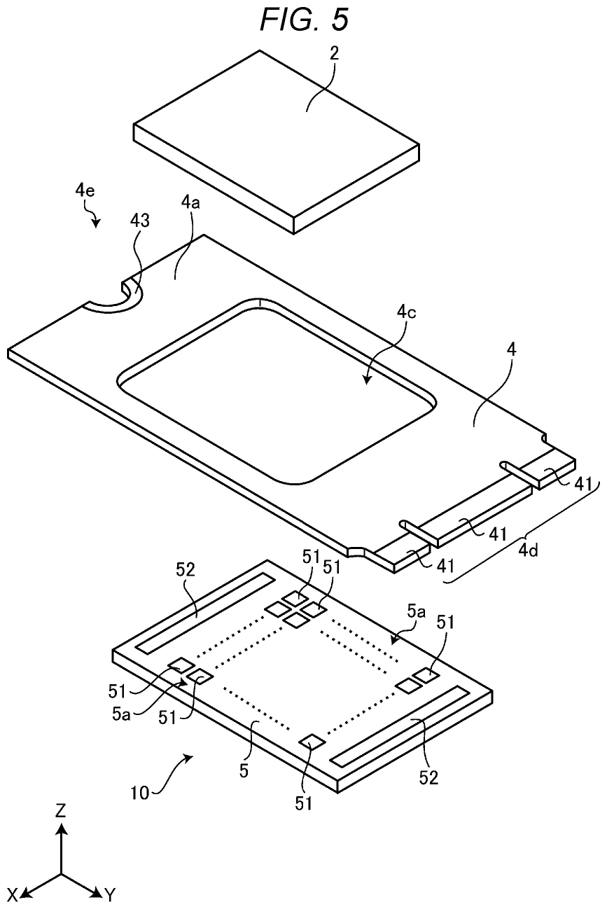

In contrast, in this embodiment, the substrate for connection to the host and the substrate for mounting the memory device 2 are separate substrates. That is, a structure 10, in which a connector portion 4d is provided on the outer edge of the perforated substrate 4 as illustrated in FIGS. 2A and 2B and the memory device 2 is mounted on the base substrate 5 through the perforated substrate 4 as illustrated in FIGS. 4 and 5, is configured. FIG. 4 is a perspective view illustrating a configuration of the structure 10. FIG. 5 is an exploded perspective view illustrating the configuration of the structure 10.

In the structure 10, a sum of a thickness H₅ of the base substrate 5, a thickness H₄ of the perforated substrate 4, and the thickness H₂ of the memory device 2 can be larger than the height H₃₁ of the internal space 31, as shown in FIG. 3 and the following Equation 5. For example, when the thickness H₂ of the memory device 2 is larger than the thickness H₄ of the perforated substrate 4, the tendency shown in Equation 5 becomes remarkable.

H₂+H₄+H₅>H₃₁ Equation 5

When the height H₃ in the Z direction of the casing 3 is equal to the predetermined height Hₜₕ, the following Equation 6 is established.

H₂+H₄+H₅>Hₜₕ−2×T₃ Equation 6

In contrast, since the memory device 2 is mounted on the base substrate 5 through the perforated substrate 4 in the structure 10, a height of the structure 10 is just a sum of the thickness H₅ of the base substrate 5 and the thickness H₂ of the memory device 2. For example, even when the thickness H₂ of the memory device 2 is larger than the thickness H₄ of the perforated substrate 4, the thickness H₄ of the perforated substrate 4 is provided in the thickness H₂ of the memory device 2, and thus the height of the structure 10 is the just the sum of the thickness H₅ of the base substrate 5 and the thickness H₂ of the memory device 2. The sum of the thickness H₅ of the base substrate 5 and the thickness H₂ of the memory device 2 can be smaller than the height H₃₁ of the inner space 31, as shown in FIG. 3 and the following Equation 7.

H₂+H₅<H₃₁ Equation 7

When the height H₃ in the Z direction of the casing 3 is equal to the predetermined height Hₜₕ, the expression H₃₁=H₃−2×T₃=Hₜₕ−2×T₃ holds, and thus, when substituting this formula into Equation 7, the following Equation 7′ is established.

H₂+H₅<Hₜₕ−2×T₃ Equation 7′

As shown in Equations 7 and 7′, the structure 10 can be accommodated in the internal space 31 of the casing 3 by mounting the memory device 2 on the base substrate 5 through the perforated substrate 4. The structure 10 can also be equivalently regarded as a structure in which the memory device 2 is mounted beyond the predetermined height Hₜₕ restriction (see Equation 6) of the first form factor standard.

On an inner surface on the +X side of the internal space 31 of the casing 3, a groove 314 corresponding to the perforated substrate 4 and a groove 315 corresponding to the base substrate 5 may be provided. Similarly, on an inner surface on the −X side of the internal space 31 of the casing 3, the groove 314 corresponding to the perforated substrate 4 and the groove 315 corresponding to the base substrate 5 may be provided.

The groove 314 on the +X side and the groove 314 on the −X side have Z positions corresponding to each other, and are positioned near the center in the Z direction. The groove 314 on the +X side and the groove 314 on the −X side each extend in the Y direction. With this configuration, the groove 314 on the +X side and the groove 314 on the −X side can guide the perforated substrate 4 so as to move in the Y direction while positioning the perforated substrate 4 near the center in the Z direction when the structure 10 is accommodated in the internal space 31.

The groove 315 on the +X side and the groove 315 on the −X side have Z positions corresponding to each other, and are positioned near a bottom surface on the −Z side. The groove 315 on the +X side and the groove 315 on the −X side each extend in the Y direction. With this configuration, the groove 315 on the +X side and the groove 315 on the −X side can guide the base substrate 5 so as to move in the Y direction while positioning the base substrate 5 near the bottom surface on the −Z side when the structure 10 is accommodated in the internal space 31.

In the structure 10, the perforated substrate 4 is positioned near the center in the Z direction in the internal space 31, as illustrated in FIGS. 2A, 2B, and 3. The perforated substrate 4 has a main surface 4a on the +Z side and a main surface 4b on the −Z side. As illustrated in FIGS. 4 and 5, the perforated substrate 4 has a hollow portion 4c penetrating from the main surface 4a to the main surface 4b in a region including the center in an XY direction. The perforated substrate 4 is provided with the connector portion 4d on the outer edge on the +Y side and a notched portion 4e on the outer edge on the −Y side. A +Y side end portion of the connector portion 4d may be positioned slightly on the −Y side of an end portion of the opening 32 of the casing 3. The connector portion 4d includes a plurality of electrodes 41. As illustrated in FIGS. 2A and 2B, the perforated substrate 4 includes a plurality of electrodes 42 near the hollow portion 4c on the main surface 4b. The plurality of electrodes 42 are connected to the electrodes 41 by wirings in the perforated substrate 4. The notched portion 4e is near a portion of the outer edge that is recessed in a substantially semicircular shape in XY plan view, and includes an electrode 43. The perforated substrate 4 may be configured with drilling a region corresponding to the hollow portion 4c with respect to a printed circuit board assembly (PCBA).

As illustrated in FIG. 2C, the connector CN of the host has a recess portion CV into which the connector portion 4d is to be fitted, and includes a plurality of electrodes EL on an inner surface on the +Z side of the recess portion CV. The plurality of electrodes EL correspond to the plurality of electrodes 41 of the connector portion 4d.

As illustrated in FIGS. 2A and 2B, an inner wall on the −Y side of the casing 3 may have a conductor protruding portion 35 protruding into the inner space 31 at a position corresponding to the electrode 43. The conductor protruding portion 35 is connected to a conductor portion of the casing 3 and has a reference voltage (for example, ground voltage) of the casing 3. When the structure 10 is accommodated in the internal space 31, the electrode 43 can electrically connect a ground layer in the perforated substrate 4 to the reference voltage of the casing 3 by contacting the conductor protruding portion 35 or the like.

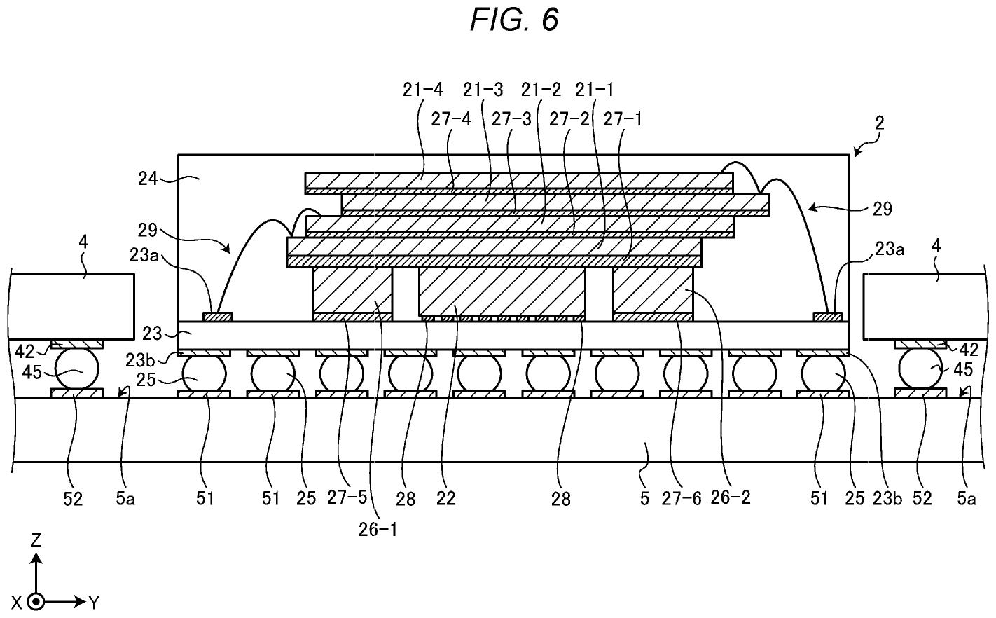

The base substrate 5 is positioned near an inner surface on the −Z side of the internal space 31, as illustrated in FIGS. 2A, 2B, and 3. The base substrate 5 has a main surface 5a on the +Z side and a main surface 5b on the −Z side. The memory device 2 is disposed on the main surface 5a of the base substrate 5. A plurality of electrodes 51 illustrated in FIG. 5 are disposed in a region corresponding to the hollow portion 4c on the main surface 5a. Each electrode 51 may have a shape corresponding to an external electrode 25 (see FIG. 6) of the memory device 2, or may have a rectangular shape in XY plan view. A plurality of electrodes 52 are disposed in a region corresponding to the outside of the hollow portion 4c in the XY direction on the main surface 5a. The base substrate 5 may be configured with the PCBA.

When comparing the perforated substrate 4 with the base substrate 5, as illustrated in FIGS. 2A and 2B, a +Y side end portion of the perforated substrate 4 is positioned on the +Y side of a +Y side end portion of the base substrate 5. With this configuration, the connector CN of the host can be easily attached to the connector portion 4d of the perforated substrate 4.

A −Y side end portion of the perforated substrate 4 may be positioned on the −Y side of a −Y side end portion of the base substrate 5. A length in the Y direction of the perforated substrate 4 may be shorter than a length in the Y direction of the base substrate 5. As illustrated in FIG. 3, a length in the X direction of the perforated substrate 4 may be equal to a length in the X direction of the base substrate 5 or may be longer than the length in the X direction of the base substrate 5. The length in the X direction of the perforated substrate 4 is desirably such that the perforated substrate 4 is accommodated in the internal space 31 of the casing 3 and is accommodated in the groove 314.

The memory device 2 is disposed inside the hollow portion 4c of the perforated substrate 4 and is disposed on the main surface 5a of the base substrate 5. The memory device 2 includes a plurality of the external electrodes 25 (see FIG. 6) on the −Z side, and is mounted on the main surface 5a by bonding the plurality of external electrodes 25 to the plurality of electrodes 51. The plurality of electrodes 51 are connected to the electrodes 52 by wirings (not illustrated) in the base substrate 5. The plurality of electrodes 52 correspond to the plurality of electrodes 42. The perforated substrate 4 is mounted on the main surface 5a outside the memory device 2 by bonding the plurality of electrodes 42 to the plurality of electrodes 52 via conductors 45.

That is, the external electrodes 25 of the memory device 2 are connected to the electrodes 41 of the connector portion 4d via the electrodes 51, the wirings in the base substrate 5, the electrodes 52, the conductors 45, the electrodes 42, and the wirings in the perforated substrate 4.

When comparing the perforated substrate 4 with the memory device 2, as illustrated in FIGS. 2A and 2B, the +Y side end portion of the perforated substrate 4 is positioned on the +Y side of a +Y side end portion of the memory device 2. The −Y side end portion of the perforated substrate 4 is positioned on the −Y side of a −Y side end portion of the memory device 2. The length in the Y direction of the perforated substrate 4 is longer than a length in the Y direction of the memory device 2.

A +Y side end portion of the hollow portion 4c of the perforated substrate 4 is positioned on the +Y side of the +Y side end portion of the memory device 2. A −Y side end portion of the hollow portion 4c of the perforated substrate 4 is positioned on the −Y side of the −Y side end portion of the memory device 2. A length in the Y direction of the hollow portion 4c of the perforated substrate 4 corresponds to the length in the Y direction of the memory device 2 and is slightly longer than the length in the Y direction of the memory device 2.

As illustrated in FIG. 3, the length in the X direction of the perforated substrate 4 is longer than a length in the X direction of the memory device 2. A length in the X direction of the hollow portion 4c of the perforated substrate 4 corresponds to the length in the X direction of the memory device 2, and is slightly longer than the length in the X direction of the memory device 2.

When comparing the base substrate 5 with the memory device 2, as illustrated in FIGS. 2A and 2B, the +Y side end portion of the base substrate 5 is positioned on the +Y side of the +Y side end portion of the memory device 2. The −Y side end portion of the base substrate 5 is positioned on the −Y side of the −Y side end portion of the memory device 2. The length in the Y direction of the base substrate 5 is longer than the length in the Y direction of the memory device 2.

As illustrated in FIG. 3, the length in the X direction of the base substrate 5 is longer than the length in the X direction of the memory device 2.

The memory device 2 includes a plurality of memory chips 21-1 to 21-4 and a controller chip 22. In the memory device 2, the plurality of memory chips 21-1 to 21-4 and the controller chip 22 may be stacked. For example, the memory device 2 may be mounted with a spacer structure as illustrated in FIG. 6. FIG. 6 is a cross-sectional view illustrating a configuration of the memory device 2. The memory chips 21-1 to 21-4 are simply referred to as a memory chip 21 when the memory chips 21-1 to 21-4 are not distinguished from each other.

The memory device 2 illustrated in FIG. 6 further includes a substrate 23, a sealing resin 24, a plurality of spacers 26-1 and 26-2, a plurality of adhesive films 27-1 to 27-6, a plurality of bumps 28, and bonding wires 29.

In the memory device 2, the controller chip 22 and the plurality of memory chips 21-1 to 21-4 are sequentially stacked on the substrate 23 via the adhesive films 27-1 to 27-4. The controller chip 22 is disposed between the lowest memory chip 21-1 among the plurality of memory chips 21-1 to 21-4 and the substrate 23. The plurality of spacers 26-1 and 26-2 are disposed on the substrate 23 on the sides of the controller chip 22 via the adhesive films 27-5 and 27-6. The controller chip 22 is flip-chip mounted on the substrate 23 via the plurality of bumps 28 in a face-down state. Each bump 28 connects a pad electrode of the controller chip 22 and an electrode of the substrate 23. The plurality of memory chips 21-1 to 21-4 are mounted on the substrate 23 by wire bonding via the plurality of bonding wires 29 in a face-up state. The memory chips 21-1 to 21-4 are respectively stacked at positions shifted in the XY direction so that the pad electrode is exposed. Each bonding wire 29 connects a pad electrode of the memory chip 21 and an electrode 23a of the substrate 23. The controller chip 22 is connected to the pad electrode of the memory chip 21 via the pad electrode of the controller chip 22, the bumps 28, the electrodes of the substrate 23, wirings in the substrate 23, the electrode 23a, and the bonding wires 29.

Although not illustrated, in the memory device 2, instead of a mounting form of the spacer structure illustrated in FIG. 6, a mounting form of a through silicon via (TSV) structure may be adopted. In this case, the plurality of memory chips 21-1 to 21-4 and the controller chip 22 are stacked and penetrated by through vias (TSVs). In the TSV structure, respective bonding wires 29 are omitted, and respective memory chips 21-1 to 21-4 may be stacked at positions aligned in the XY direction.

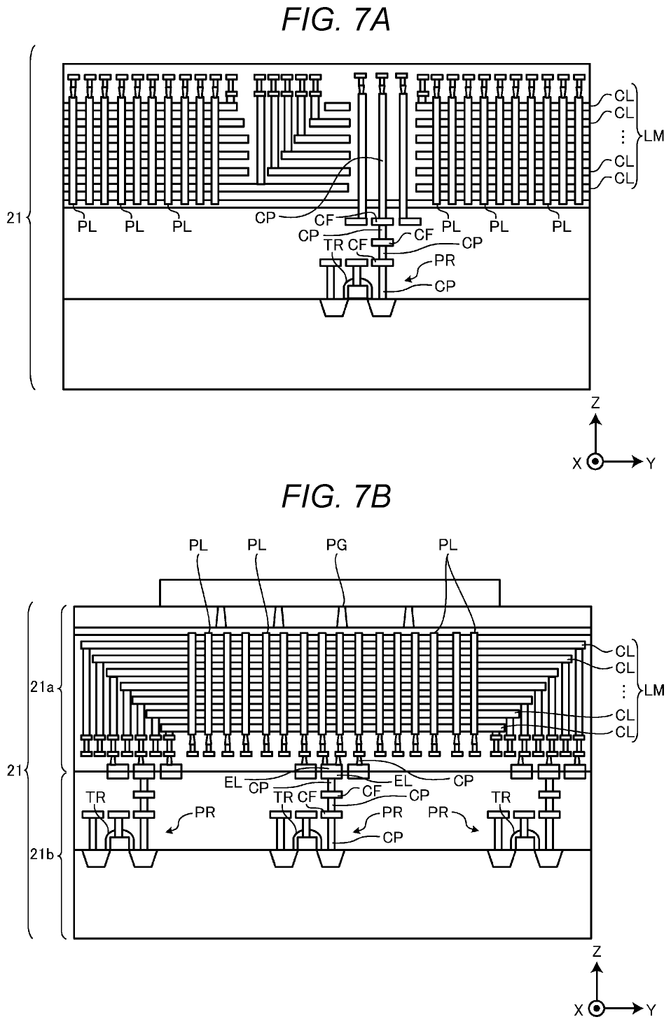

Each memory chip 21 may be a nonvolatile memory chip, such as a NAND flash memory. Each memory chip 21 may be a three-dimensional memory chip. For example, for each memory chip 21, a structure illustrated in FIG. 7A may be adopted, or a structure illustrated in FIG. 7B may be adopted. FIGS. 7A and 7B are YZ cross-sectional views illustrating a configuration of the memory chip 21.

Both the structure illustrated in FIG. 7A and the structure illustrated in FIG. 7B include a stacked body LM and semiconductor pillars PL. In the stacked body LM, a plurality of conductive layers CL are stacked via insulating layers. The stacked body LM is penetrated in a stacking direction by the semiconductor pillars PL and insulating films covering side surfaces of the semiconductor pillars PL. With this configuration, a three-dimensional memory is configured. Since the memory capacity of the memory chip 21 can be increased by increasing the number of stacked layers, the need to use more advanced patterning technology can be reduced and the cost per bit can be easily reduced. In this three-dimensional memory, portions where the conductive layers CL and the semiconductor pillars PL intersect are configured to function as memory cells, and a memory cell array region in which a plurality of memory cells are located three-dimensionally is configured.

In the structure illustrated in FIG. 7A, a peripheral circuit region is provided below the memory cell array region in order to increase integration density of the memory chip 21. Each of the semiconductor pillars PL is connected to a peripheral circuit PR via the upper layer wiring, a plurality of contact plugs CP, and conductive films CF.

In the structure illustrated in FIG. 7B, in order to increase integration density of the memory chip 21, the memory chip 21 is manufactured by bonding a wafer including a memory cell array region 21a and a wafer including a peripheral circuit region 21b. Each of the semiconductor pillars PL is connected to the peripheral circuit PR via contact plugs CP in the memory cell array region 21a, electrodes EL in the memory cell array region 21a, electrodes EL in the peripheral circuit region 21b, and a plurality of contact plugs CP and conductive films CF in the peripheral circuit region 21b. The electrodes EL are, for example, copper (Cu).

With the configuration illustrated in FIG. 6, FIG. 7A, or FIG. 7B, the thickness H₂ of the memory device 2 in the Z direction easily becomes thick.

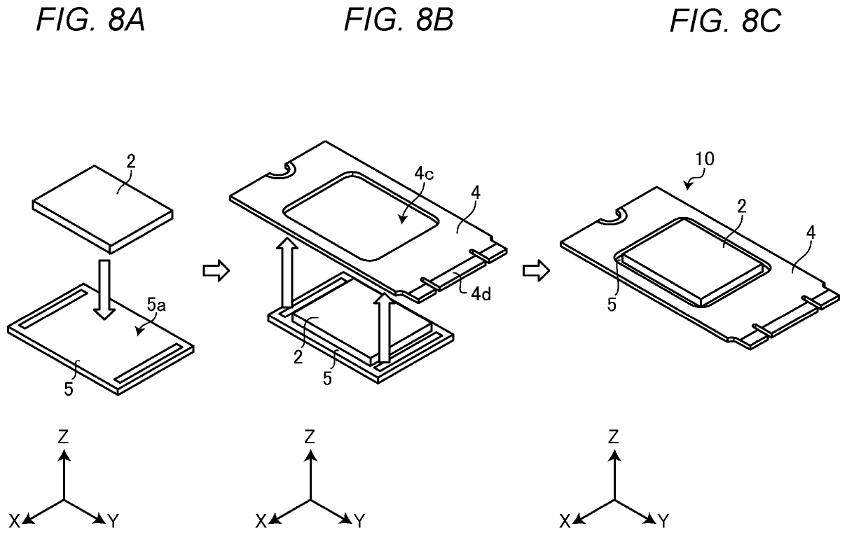

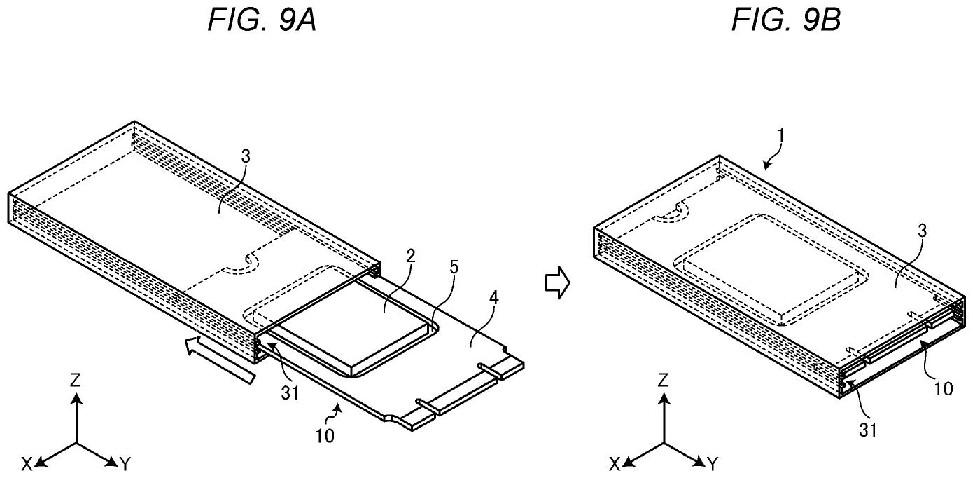

Next, a method for manufacturing the semiconductor storage device 1 will be described with reference to FIGS. 8A to 9B. FIGS. 8A to 9B are perspective views illustrating the method for manufacturing the semiconductor storage device 1.

In a step illustrated in FIG. 8A, the memory device 2 is mounted on the main surface 5a of the base substrate 5. The memory device 2 is mounted on the main surface 5a by bonding the plurality of external electrodes 25 (see FIG. 6) to the plurality of electrodes 51 (see FIG. 5). The bonding may be alloy bonding by heating each electrode, or may be solder bonding in which the bonding is made by heating and melting solder between the electrodes.

In a step illustrated in FIG. 8B, the perforated substrate 4 is disposed on the +Z side of the structure in which the memory device 2 is mounted on the base substrate 5. The perforated substrate 4 is aligned so that the hollow portion 4c is at the XY position corresponding to the memory device 2 and the connector portion 4d is on the +Y side. The perforated substrate 4 is brought closer to the base substrate 5 in the Z direction, and the perforated substrate 4 is mounted on the main surface 5a of the base substrate 5. The perforated substrate 4 is mounted on the main surface 5a outside the memory device 2 by bonding the plurality of electrodes 42 (see FIG. 6) to the plurality of electrodes 52 via the plurality of conductors 45. The bonding may be alloy bonding by heating each electrode, or may be solder bonding in which the bonding is made by heating and melting solder between the electrodes.

Thus, the structure 10 illustrated in FIG. 8C is obtained. In the structure 10, the memory device 2 is mounted on the base substrate 5 through the perforated substrate 4.

In a step illustrated in FIG. 9A, the structure 10 is accommodated in the internal space 31 from the +Y side of the casing 3. In this case, the groove 314 on the +X side and the groove 314 on the −X side (see FIG. 3) of the internal space 31 of the casing 3 guide the perforated substrate 4 so as to move in the Y direction while positioning the perforated substrate 4 near the center in the Z direction. The groove 315 on the +X side and the groove 315 on the −X side guide the base substrate 5 so as to move in the Y direction while positioning the base substrate 5 near the bottom surface on the −Z side.

Thus, the semiconductor storage device 1 illustrated in FIG. 9B is obtained. In the semiconductor storage device 1, the structure 10 is accommodated in the internal space 31 of the casing 3.

As described above, in the first embodiment, in the semiconductor storage device 1, the structure 10, in which the connector portion 4d is provided on the outer edge of the perforated substrate 4 and the memory device 2 is mounted on the base substrate 5 through the perforated substrate 4, is configured according to the first form factor standard, for example. With this configuration, the memory device 2 can be compactly mounted, and the structure 10 including the memory device 2 can be accommodated in the casing 3.

### Second Embodiment

Next, a semiconductor storage device 1j according to a second embodiment will be described. In the following, description will be mainly made on portions that are different from the first embodiment.

In the first embodiment, a configuration in which the connector portion 4d of the perforated substrate 4 is accommodated in the casing 3 is illustrated, but, in the second embodiment, a configuration in which a casing 3j is configured with a base 33j and a cover 34j, and the connector portion 4d of the perforated substrate 4 protrudes outside the casing 3j is illustrated.

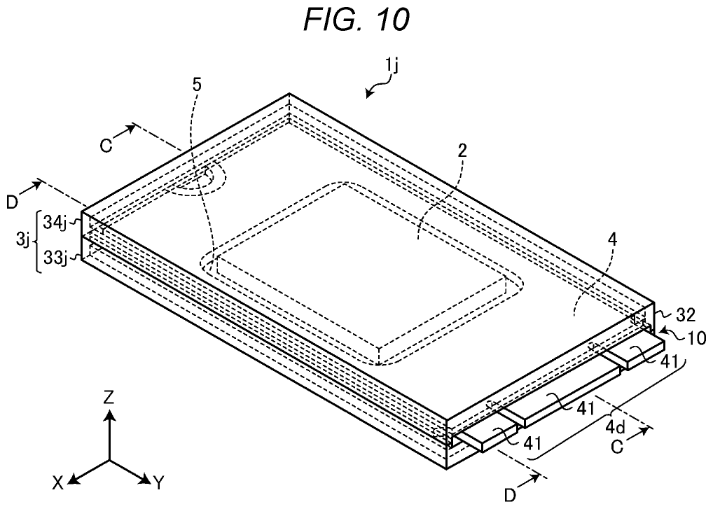

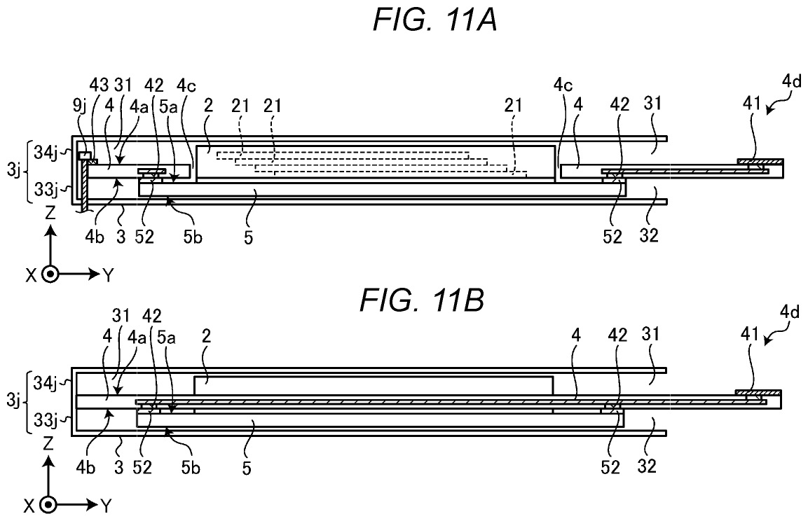

The semiconductor storage device 1j may be configured as illustrated in FIG. 10 according to the first form factor standard. FIG. 10 is a perspective view illustrating a configuration of the semiconductor storage device 1j. The memory device 2, the base substrate 5, and the perforated substrate 4 illustrated in FIG. 10 are accommodated in the casing 3j as illustrated in FIGS. 11A and 11B.

FIGS. 11A and 11B are YZ cross-sectional views illustrating the configuration of the semiconductor storage device 1j. FIG. 11A is a YZ cross-sectional view illustrating a configuration of a cross section including the memory device 2 of the semiconductor storage device 1j, and illustrates a YZ cross section taken along line C-C of FIG. 10. FIG. 11B is a YZ cross-sectional view illustrating a configuration of a cross section not including the memory device 2 of the semiconductor storage device 1j, and illustrates a YZ cross section taken along line D-D of FIG. 10.

In this case, the connector portion 4d of the perforated substrate 4 is positioned on the +Y side of the opening 32 of the casing 3j, and is disposed outside the internal space 31 of the casing 3j. With this configuration, the connector CN of the host (see FIG. 2C) can be attached more easily.

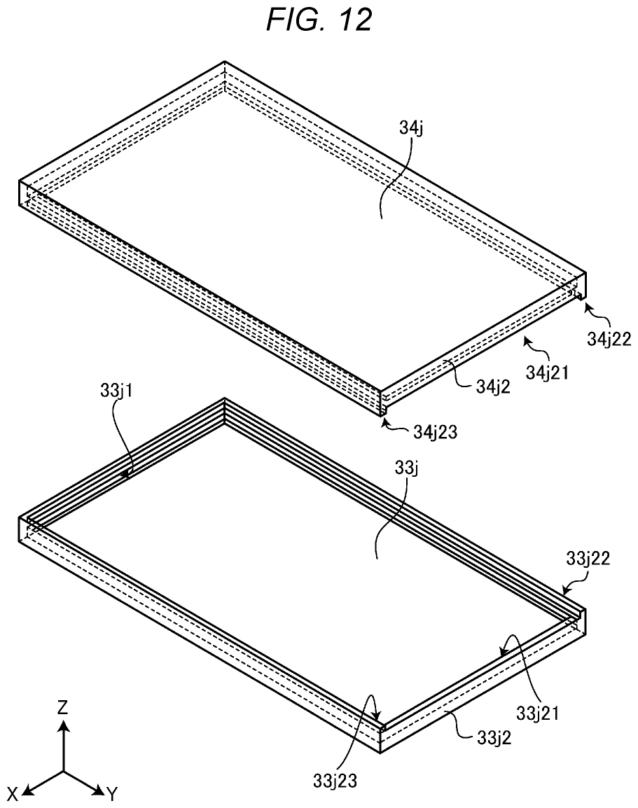

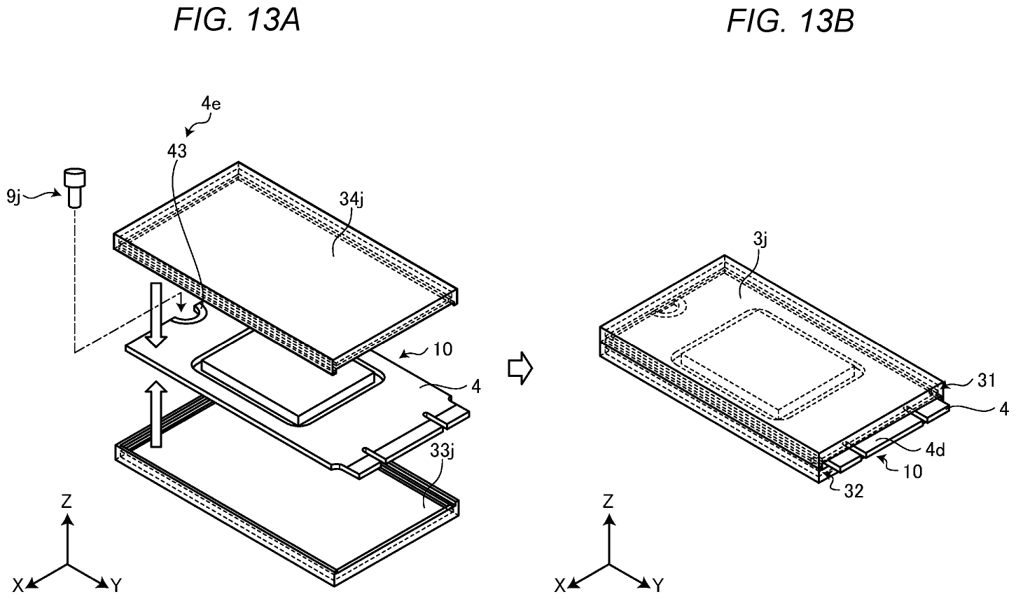

The casing 3j may include the base 33j and the cover 34j, as illustrated in FIGS. 11A, 11B, and 12. FIG. 12 is an exploded perspective view illustrating a configuration of the casing 3j. The base 33j and the cover 34j have shapes corresponding to each other. The base 33j has a box shape with the +Z side open, and the cover 34j has a box shape with the −Z side open. The base 33j is provided with a recess portion 33j21 recessed slightly to the −Z side from both ends 33j22 and 33j23 at the +Z side end portion of a +Y side wall portion 33j2. The cover 34j is provided with a recess portion 34j21 recessed slightly to the +Z side from both ends 34j22 and 34j23 at the −Z side end portion of a +Y side wall portion 34j2. The base 33j and the cover 34j form the opening 32 (see FIG. 13B) by coupling the recess portion 34j21 and the recess portion 33j21 in a state where the base 33j and the cover 34j are fitted to each other. The base 33j has a hole 33j1 corresponding to a fastening member 9j (see FIG. 11A) near the −Y side end portion on the bottom surface. When the fastening member 9j is a screw, a screw groove may be formed on the inner surface of the hole 33j1.

The cover 34j has a box shape with the −Z side and +Y side open. Side surfaces of the cover 34j on the −X side, −Y side, and +X side are coupled to side surfaces of the base 33j on the −X side, −Y side, and +X side to form the internal space 31 of the casing 3j (see FIGS. 11A and 11B).

Further, as illustrated in FIGS. 13A and 13B, a method for manufacturing the semiconductor storage device 1j differs from the first embodiment in the following points. FIGS. 13A and 13B are perspective views illustrating the method for manufacturing the semiconductor storage device 1j.

After the steps of FIGS. 8A to 8C are performed and the structure 10 is formed, a step illustrated in FIG. 13A is performed. In the step illustrated in FIG. 13A, the structure 10 is screwed to the base 33j by the fastening member 9j. In this case, screwing is performed so that the −Z side surface of the top portion of the fastening member 9j contacts the electrode 43. With this configuration, the electrode 43 of the notched portion 4e can electrically connect the ground layer in the perforated substrate 4 to a reference voltage (for example, ground voltage) of the casing 3j.

Fitting structures are provided on the −Z side end portions of the side surfaces of the cover 34j on the −X side, −Y side, and +X side and the +Z side end portions of the side surfaces of the base 33j on the −X side, −Y side, and +X side, respectively. The side surfaces of the cover 34j on the −X side, −Y side, and +X side are coupled to the side surfaces of the base 33j on the −X side, −Y side, and +X side via the fitting structures. The +Z side opening of the base 33j is covered with the cover 34j. The −Z side opening of the cover 34j is covered with the base 33j. Thus, the casing 3j is configured.

With this configuration, as illustrated in FIG. 13B, the structure 10 is accommodated in the internal space 31 of the casing 3j in a state where the connector portion 4d of the perforated substrate 4 protrudes outside the internal space 31 of the casing 3j. The internal space 31 of the casing 3j is opened by the opening 32 on the +Y side and closed by the base 33j and the cover 34j on the other sides than the +Y side (see FIGS. 11A and 11B).

As described above, in the second embodiment, also in the semiconductor storage device 1j, the structure 10, in which the connector portion 4d is provided on the outer edge of the perforated substrate 4 and the memory device 2 is mounted on the base substrate 5 through the perforated substrate 4, is configured according to the first form factor standard, for example. With this configuration, the memory device 2 can be compactly mounted, and the structure 10 including the memory device 2 can be accommodated in the casing 3j.

### Third Embodiment

Next, a semiconductor storage device 1k according to a third embodiment will be described. In the following, description will be mainly made on portions that are different from the first and second embodiments.

In the first and second embodiments, the configuration in which the memory device 2 is mounted on the base substrate 5 is illustrated, but, in the third embodiment, a configuration in which a memory device 2k is mounted on the base substrate 5 via a socket 6k is illustrated.

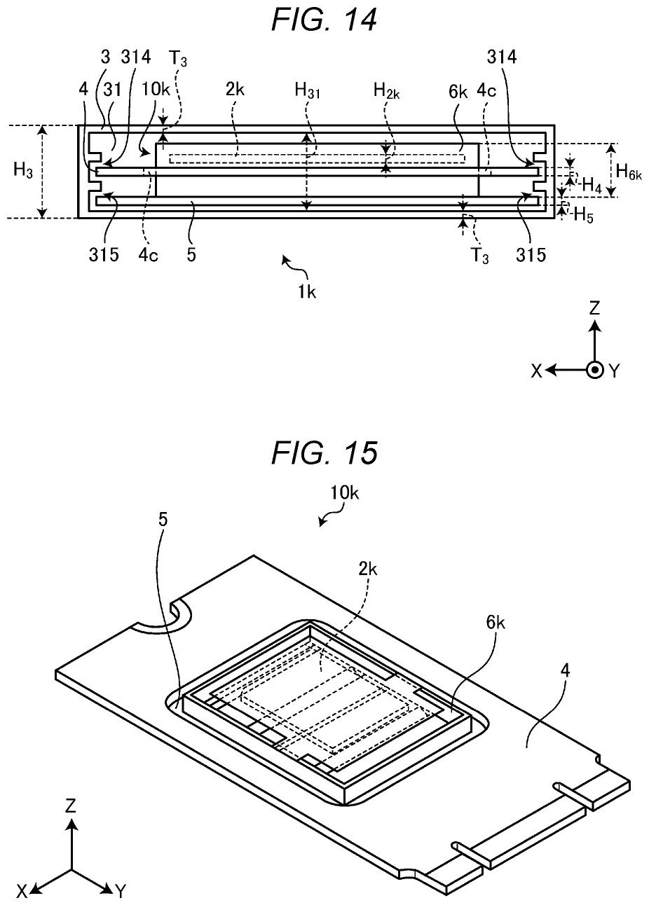

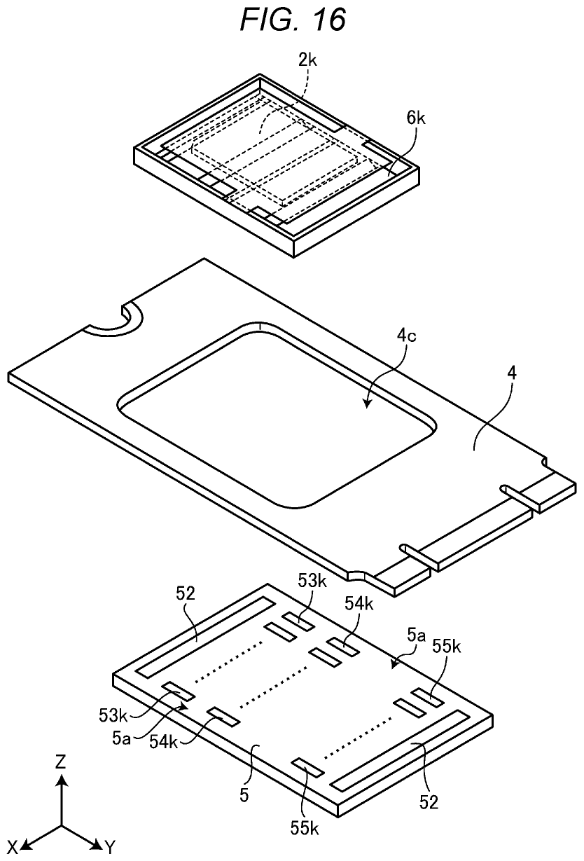

The semiconductor storage device 1k may be configured as illustrated in FIGS. 14 to 16 according to the first form factor standard. FIG. 14 is a front view illustrating a configuration of the semiconductor storage device 1k, and is a front view of the semiconductor storage device 1k when viewed from the +Y side. FIG. 15 is a perspective view illustrating a configuration of a structure 10k. FIG. 16 is an exploded perspective view illustrating the configuration of the structure 10k.

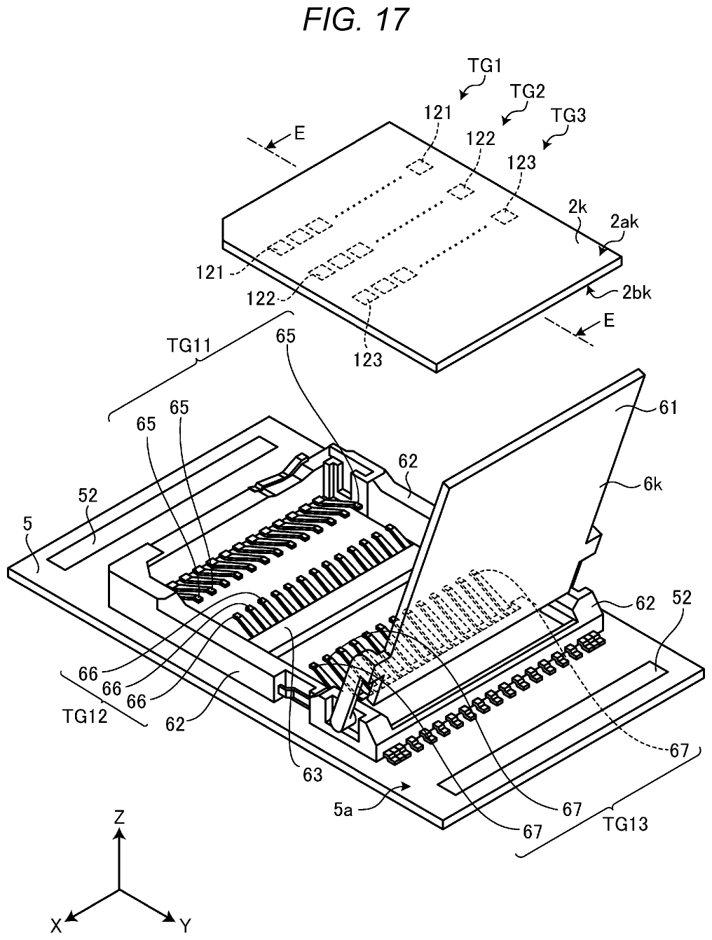

As illustrated in FIGS. 14 to 16, the structure 10k, in which the socket 6k to which the memory device 2k is attached is mounted on the base substrate 5 through the perforated substrate 4, is configured. The memory device 2k may be a memory card such as an SD card. The memory device 2k can be attached to and detached from the socket 6k. FIGS. 15 and 16 illustrate a state in which the memory device 2k is attached to the socket 6k, and FIG. 17 illustrates a state in which the memory device 2k is detached from the socket 6k.

In the structure 10k, a thickness H₆ₖ of the socket 6k includes a thickness of a member such as a lid portion 61 (see FIG. 17) in addition to a thickness H₂ₖ of the memory device 2k. The thickness H₆ₖ of the socket 6k includes the thickness H₂ₖ of the memory device 2k and is thicker than the thickness H₂ₖ of the memory device 2k, as shown in Equation 8 below.

H₆ₖ>H₂ₖ Equation 8

A sum of the thickness H₅ of the base substrate 5, the thickness H₄ of the perforated substrate 4, and the thickness H₆ₖ of the socket 6k can be larger than the height H₃₁ of the internal space 31 (see FIG. 3), as shown in FIG. 14 and the following Equation 9. For example, when the thickness H₆ₖ of the socket 6k is thicker than the thickness H₄ of the perforated substrate 4, the tendency shown in Equation 9 becomes remarkable.

H₆ₖ+H₄+H₅>H₃₁ Equation 9

When the height H₃ in the Z direction of the casing 3 is equal to the predetermined height Hₜₕ, the following Equation 10 is established.

H₆ₖ+H₄+H₅>Hₜₕ−2×T₃ Equation 10

In contrast, even when the thickness H₆ₖ of the socket 6k is thicker than the thickness H₄ of the perforated substrate 4, since the socket 6k is mounted on the base substrate 5 through the perforated substrate 4, a height of the structure 10k is just a sum of the thickness H₅ of the base substrate 5 and the thickness H₆ₖ of the socket 6k. The sum of the thickness H₅ of the base substrate 5 and the thickness H₆ₖ of the socket 6k can be smaller than the height H₃₁ of the internal space 31, as shown in FIG. 14 and the following Equation 11.

H₆ₖ+H₅<H₃₁ Equation 11

As shown in Equation 11, the structure 10k can be accommodated in the internal space 31 of the casing 3 by mounting the socket 6k on the base substrate 5 through the perforated substrate 4. The structure 10 can also be equivalently regarded as a structure in which the socket 6k is mounted beyond the predetermined height Hₜₕ restriction (see Equation 10) of the first form factor standard.

In the structure 10k, as illustrated in FIGS. 15 and 16, the socket 6k is disposed on the main surface 5a of the base substrate 5. A plurality of electrodes 53k, a plurality of electrodes 54k, and a plurality of electrodes 55k illustrated in FIG. 16 are disposed in a region corresponding to the hollow portion 4c on the main surface 5a. Each electrode 53k may have a shape corresponding to a connection terminal 65 (see FIG. 17) of the socket 6k, or may have a strip shape extending in the Y direction in XY plan view. Each electrode 54k may have a shape corresponding to a connection terminal 66 (see FIG. 17) of the socket 6k, or may have a strip shape extending in the Y direction in XY plan view. Each electrode 55k may have a shape corresponding to a connection terminal 67 (see FIG. 17) of the socket 6k, or may have a strip shape extending in the Y direction in XY plan view.

As illustrated in FIGS. 14 to 16, the memory device 2k is positioned in the socket 6k when attached to the socket 6k. As illustrated in FIG. 17, the memory device 2k has a main surface 2ak on the +Z side and a main surface 2bk on the −Z side. FIG. 17 is a perspective view illustrating a configuration of the memory device 2k and the socket 6k. The memory device 2k includes a terminal group TG1, a terminal group TG2, and a terminal group TG3 on the main surface 2bk. The terminal group TG1, the terminal group TG2, and the terminal group TG3 are spaced apart from each other in the Y direction within the main surface 2bk.

The terminal group TG1 includes a plurality of electrode terminals 121. The plurality of electrode terminals 121 are located in the X direction in the main surface 2bk. Each electrode terminal 121 has, for example, a substantially rectangular shape whose longitudinal direction is the Y direction.

The terminal group TG2 includes a plurality of electrode terminals 122. The plurality of electrode terminals 122 are located in the X direction in the main surface 2bk. Each electrode terminal 122 has, for example, a substantially rectangular shape whose longitudinal direction is the Y direction.

The terminal group TG3 includes a plurality of electrode terminals 123. The plurality of electrode terminals 123 are located in the X direction in the main surface 2bk. Each electrode terminal 123 has, for example, a substantially rectangular shape whose longitudinal direction is the Y direction.

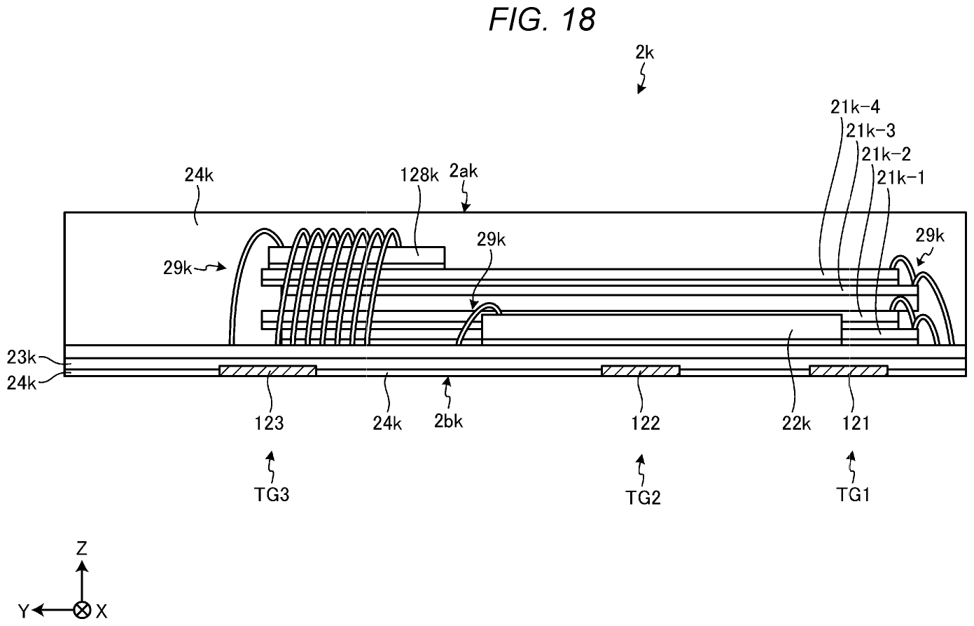

As illustrated in FIG. 18, the memory device 2k further includes memory chips 21k-1 to 21k-4, the controller chip 22k, a buffer chip 128k, a sealing portion 24k, and a substrate 23k. FIG. 18 is a cross-sectional view illustrating the configuration of the memory device 2k. FIG. 18 illustrates a cross section taken along line E-E of FIG. 17.

On the +Z side surface of the substrate 23k, a plurality of the memory chips 21k-1 to 21k-4 are stacked and the controller chip 22k is disposed. The buffer chip 128k may be further stacked on the +Z side of the memory chip 21k-4 closest to the +Z side. The terminal group TG1, the terminal group TG2, and the terminal group TG3 are disposed on the −Z side surface of the substrate 23k.

The sealing portion 24k covers the +Z side of the substrate 23k, and accommodates the memory chips 21k-1 to 21k-4, the controller chip 22k, the buffer chip 128k, and the substrate 23k. The sealing portion 24k can be made of a thermoplastic insulating material such as mold resin. The sealing portion 24k covers the −Z side of the substrate 23k and exposes the terminal group TG1, the terminal group TG2, and the terminal group TG3. The −Z side surface of the sealing portion 24k forms the main surface 2bk of the memory device 2k, and the +Z side surface of the sealing portion 24k forms the main surface 2ak of the memory device 2k. The sealing portion 24k can be made of mold resin.

As illustrated in FIG. 17, the socket 6k includes the lid portion 61, a wall portion 62, a beam portion 63, a connection terminal group TG11, a connection terminal group TG12, and a connection terminal group TG13.

The wall portion 62 is disposed on the main surface 5a of the base substrate 5. The wall portion 62 has a substantially rectangular frame shape in XY plan view. The wall portion 62 forms a recessed space corresponding to the memory device 2k. A width in the X direction of the recessed space corresponds to a width in the X direction of the memory device 2k, and a width in the Y direction of the recessed space corresponds to a width in the Y direction of the memory device 2k.

The beam portion 63 extends in the X direction at a position near the center in the Y direction in the recessed space formed by the wall portion 62. With this configuration, the beam portion 63 connects a +X side portion and a −X side portion of the wall portion 62.

The connection terminal group TG11 is disposed on an inner surface on the −Y side of the wall portion 62 and positioned in the recessed space. The connection terminal group TG11 includes a plurality of the connection terminals 65. The plurality of connection terminals 65 correspond to the plurality of electrode terminals 121 of the terminal group TG1 in the memory device 2k. Each connection terminal 65 protrudes from the inner surface on the −Y side of the wall portion 62 to the +Y side and the +Z side toward a position where the connection terminal 65 can contact the corresponding electrode terminal 121 when the memory device 2k is attached.

The connection terminal group TG12 is disposed on an inner surface of the +Y side of the beam portion 63 and positioned in the recessed space. The connection terminal group TG12 includes a plurality of the connection terminals 66. The plurality of connection terminals 66 correspond to the plurality of electrode terminals 122 of the terminal group TG2 in the memory device 2k. Each connection terminal 66 protrudes from the inner surface on the +Y side of the beam portion 63 to the −Y side and the +Z side toward a position where the connection terminal 66 can contact the corresponding electrode terminal 122 when the memory device 2k is attached.

The connection terminal group TG13 is disposed on an inner surface on the +Y side of the wall portion 62 and positioned in the recessed space. The connection terminal group TG13 includes a plurality of the connection terminals 67. The plurality of connection terminals 67 correspond to the plurality of electrode terminals 123 of the terminal group TG3 in the memory device 2k. Each connection terminal 67 protrudes from the inner surface on the +Y side of the wall portion 62 to the −Y side and the +Z side toward a position where the connection terminal 67 can contact the corresponding electrode terminal 123 when the memory device 2k is attached.

The lid portion 61 is rotatably attached to both +Y side end portions of the wall portion 62 in the X direction. As illustrated in FIG. 17, the lid portion 61 opens the recessed space in an open state by being pulled up to the +Z side. As illustrated in FIG. 15, the lid portion 61 closes the recessed space in a closed state by being pulled down to the −Z side.

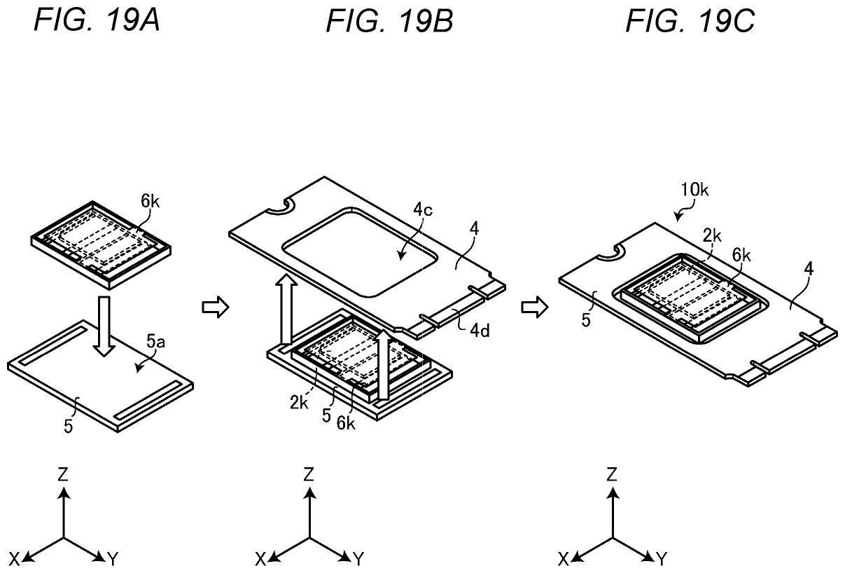

Further, as illustrated in FIGS. 17 and 19A to 19C, a method for manufacturing the semiconductor storage device 1k differs from the first and second embodiments in the following points. FIGS. 19A to 19C are perspective views illustrating the method for manufacturing the semiconductor storage device 1k. FIG. 17 is the perspective view illustrating the configuration of the memory device 2k and the socket 6k, and is also used as a perspective view illustrating the method for manufacturing the semiconductor storage device 1k.

In a step illustrated in FIG. 19A, the socket 6k is mounted on the main surface 5a of the base substrate 5. The socket 6k is mounted on the main surface 5a by bonding the plurality of connection terminals 65 (see FIG. 17) to the plurality of electrodes 53k (see FIG. 16), bonding the plurality of connection terminals 66 to the plurality of electrodes 54k, and bonding the plurality of connection terminals 67 to the plurality of electrodes 55k. The bonding may be alloy bonding by heating each electrode, or may be solder bonding in which the bonding is made by heating and melting solder between the electrodes.

In the step illustrated in FIG. 17, with the lid portion 61 pulled up to the +Z side and opened, the memory device 2k is fitted into the recessed space and the memory device 2k is attached to the socket 6k. After that, the lid portion 61 is closed, the memory device 2k is accommodated in the socket 6k, and the attachment of the memory device 2k to the socket 6k is completed.

The lid portion 61 can press the memory device 2k toward the −Z side by the weight of the lid portion 61 or by fitting the lid portion 61 in the closed state into a predetermined fitting portion of the wall portion 62. Accordingly, each electrode terminal 121 of the terminal group TG1 on the main surface 2bk of the memory device 2k contacts the corresponding connection terminal 65 of the connection terminal group TG11. Each electrode terminal 122 of the terminal group TG2 on the main surface 2bk of the memory device 2k contacts the corresponding connection terminal 66 of the connection terminal group TG12. Each electrode terminal 123 of the terminal group TG3 on the main surface 2bk of the memory device 2k contacts the corresponding connection terminal 67 of the connection terminal group TG13.

In a step illustrated in FIG. 19B, the perforated substrate 4 is disposed on the +Z side of the structure in which the socket 6k to which the memory device 2k is attached is mounted on the base substrate 5. The perforated substrate 4 is aligned so that the hollow portion 4c is at the XY position corresponding to the socket 6k and the connector portion 4d is on the +Y side. The perforated substrate 4 is brought closer to the base substrate 5 in the Z direction, and the perforated substrate 4 is mounted on the main surface 5a of the base substrate 5. The perforated substrate 4 is mounted on the main surface 5a outside the socket 6k by bonding the plurality of electrodes 42 (see FIG. 6) to the plurality of electrodes 52 via the plurality of conductors 45. The bonding may be alloy bonding by heating each electrode, or may be solder bonding in which the bonding is made by heating and melting solder between the electrodes.

Thus, the structure 10k illustrated in FIG. 19C is obtained. In the structure 10k, the socket 6k to which the memory device 2k is attached is mounted on the base substrate 5 through the perforated substrate 4.

After that, in the same manner as the steps illustrated in FIGS. 9A and 9B, the structure 10k is accommodated in the internal space 31 of the casing 3, and the semiconductor storage device 1k is configured.

As described above, in the third embodiment, in the semiconductor storage device 1k, the structure 10k, in which the connector portion 4d is provided on the outer edge of the perforated substrate 4 and the socket 6k to which the memory device 2k is attached is mounted on the base substrate 5 through the perforated substrate 4, is configured according to the first form factor standard, for example. With this configuration, the memory device 2k can be compactly mounted, and the structure 10k including the memory device 2k can be accommodated in the casing 3.

A casing in which the structure 10k is accommodated may be the casing 3j (see FIG. 10) instead of the casing 3 (see FIG. 14). In this case, the connector portion 4d of the perforated substrate 4 may be disposed outside the internal space 31 of the casing 3j.

### Fourth Embodiment

Next, a semiconductor storage device 1n according to a fourth embodiment will be described. In the following, description will be mainly made on portions that are different from the first and second embodiments.

In the first to third embodiments, the configuration according to the first form factor standard is illustrated, but in the fourth embodiment, a configuration according to a second form factor standard is illustrated. The second form factor standard is a form factor standard in which a substrate is accommodated in a case CS of a host HS, and may be M.2 standard.

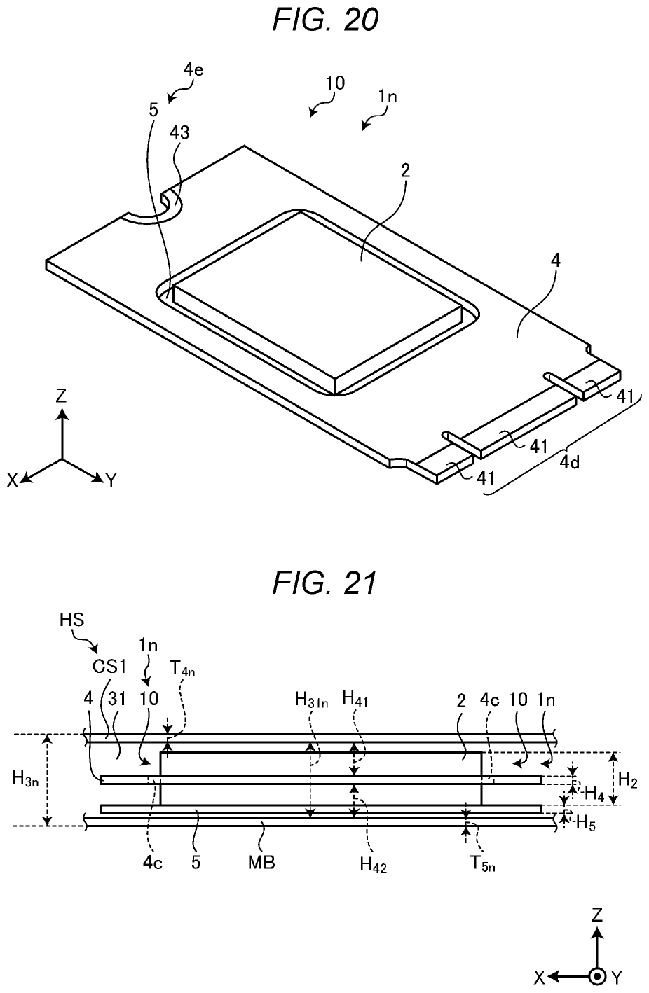

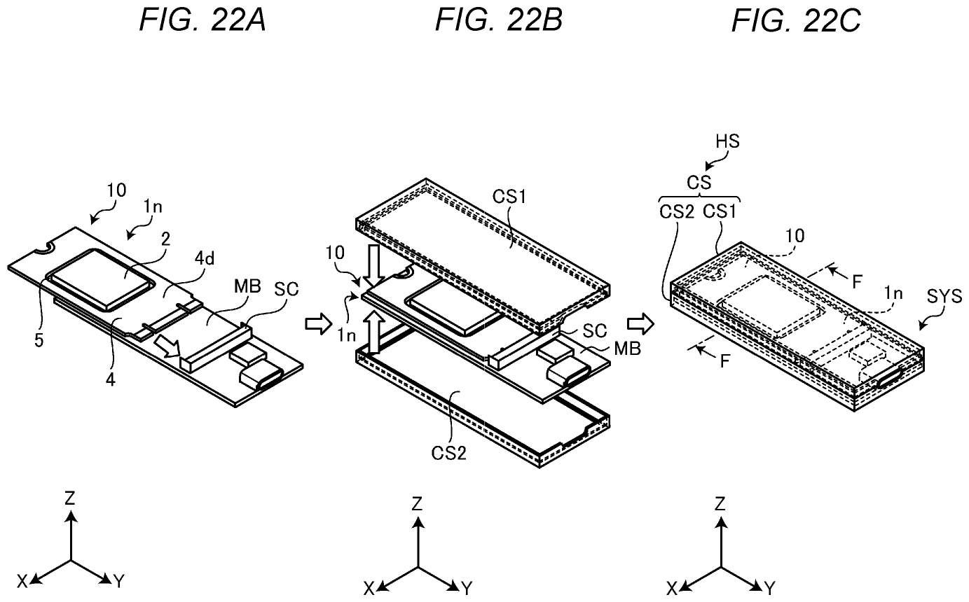

The semiconductor storage device In can be configured as illustrated in FIG. 20 according to the second form factor standard. FIG. 20 is a perspective view illustrating a configuration of the semiconductor storage device 1n. The semiconductor storage device 1n has the same configuration as the structure 10 of the first embodiment (see FIG. 4), but differs from the structure 10 of the first embodiment in that the semiconductor storage device 1n is subjected to the height restriction of the second form factor standard, as illustrated in FIG. 21. FIG. 21 is a cross-sectional view illustrating a configuration of the structure 10 of the semiconductor storage device 1n, and corresponds to a cross-section taken along line F-F of FIG. 22C described later.

Here, the semiconductor storage device 1n can be attached to a motherboard MB of the host HS. The semiconductor storage device 1n is accommodated in the case CS of the host HS while being attached to the motherboard MB of the host HS. The case CS includes a base CS2 on the −Z side and a cover CS1 on the +Z side. Of these, FIG. 21 illustrates a space between the cover CS1 and the motherboard MB of the host HS.

In the second form factor standard, as illustrated in FIG. 21, a sum of a +Z side height H₄₁, a thickness H₄, and a −Z side height H₄₂ of a substrate (in this case, perforated substrate 4) on which the connector portion 4d is provided is restricted to a predetermined height Hₜₕₙ or less. Accordingly, a gap H₃₁ₙ in the Z direction between the motherboard MB and the cover CS1 of the host HS in which the semiconductor storage device 1n is provided is configured to satisfy the following Equation 12.

H₃₁ₙ≤Hₜₕₙ Equation 12

In the semiconductor storage device 1n, the structure 10, in which the connector portion 4d is provided on the outer edge of the perforated substrate 4 and the memory device 2 is mounted on the base substrate 5 through the perforated substrate 4, is configured as illustrated in FIGS. 20 and 21.

The structure 10 is attached to the motherboard MB and accommodated in the case CS. The structure 10 is disposed in a space between the motherboard MB and the cover CS1 while being attached to the motherboard MB and accommodated in the case CS.

In the structure 10, a sum of the thickness H₅ of the base substrate 5, the thickness H₄ of the perforated substrate 4, and the thickness H₂ of the memory device 2 can be larger than the gap H₃₁ₙ in the Z direction between the motherboard MB and the cover CS1, as shown in FIG. 21 and the following Equation 13. For example, when the thickness H₂ of the memory device 2 is larger than the thickness H₄ of the perforated substrate 4, the tendency shown in Equation 13 becomes remarkable.

H₂+H₄+H₅>H₃₁ₙ Equation 13

When the gap H₃₁ₙ in the Z direction between the motherboard MB and the cover CS1 is equal to the predetermined height Hₜₕₙ, the following Equation 14 is established.

H₂+H₄+H₅>Hₜₕₙ Equation 14

In contrast, since the memory device 2 is mounted on the base substrate 5 through the perforated substrate 4, a height of the structure 10 is just a sum of the thickness H₅ of the base substrate 5 and the thickness H₂ of the memory device 2. For example, even when the thickness H₂ of the memory device 2 is larger than the thickness H₄ of the perforated substrate 4, since the thickness H₄ of the perforated substrate 4 is included in the thickness H₂ of the memory device 2, the height of the structure 10 is just the sum of the thickness H₅ of the base substrate 5 and the thickness H₂ of the memory device 2. The sum of the thickness H₅ of the base substrate 5 and the thickness H₂ of the memory device 2 can be smaller than the gap H₃₁ₙ in the Z direction between the motherboard MB and the cover CS1, as shown in FIG. 21 and the following Equation 15.

H₂+H₅<H₃₁ₙ Equation 15

When the height H₃ₙ in the Z direction of the casing 3 is equal to the predetermined height Hₜₕₙ, an expression H₃₁ₙ=H₃ₙ−T₄ₙ−T₅ₙ=Hₜₕₙ−T₄ₙ−T₅ₙ holds, and thus, when substituting this formula into Equation 15, the following Equation 15′ is established.

H₂+H₅<Hₜₕₙ−T₄ₙ−T₅ₙ Equation 15′

As shown in Equations 15 and 15′, the structure 10 can be accommodated within the gap H₃₁ₙ in the Z direction between the motherboard MB and the cover CS1 by mounting the memory device 2 on the base substrate 5 through the perforated substrate 4. The structure 10 can also be equivalently regarded as a structure in which the memory device 2 is mounted beyond the predetermined height Hₜₕₙ restriction (see Equation 14) of the second form factor standard.

As illustrated in FIGS. 22A to 22C, a method for manufacturing the semiconductor storage device 1n differs from the first to third embodiments in the following points. FIGS. 22A to 22C are perspective views illustrating the method for manufacturing the semiconductor storage device 1n. Although FIGS. 22A to 22C illustrate a case where the host HS in which the semiconductor storage device 1n is provided is a portable terminal such as a smart phone, the host HS may be any equipment or device that supports the second form factor standard, and may be a laptop personal computer.

After the steps of FIGS. 8A to 8C are performed and the structure 10 is formed, a step illustrated in FIG. 22A is performed. In the step illustrated in FIG. 22A, the structure 10 is attached to a socket SC provided on the +Z side surface of the motherboard MB so as to be inserted from the −Y side. Although not illustrated, the socket SC has a recess portion into which the connector portion 4d is fitted, and includes a plurality of electrodes on an inner surface on the +Z side of the recess portion. The plurality of electrodes correspond to the plurality of electrodes 41 of the connector portion 4d.

In a step illustrated in FIG. 22B, fitting structures are provided on the −Z side end portions of side surfaces of the cover CS1 of the host HS on the −X side, −Y side, +X side, and +Y side and the +Z side end portions of side surfaces of the base CS2 of the host HS on the −X side, −Y side, +X side, and +Y side, respectively. The side surfaces of the cover CS1 on the −X side, −Y side, +X side, and +Y side are coupled to the side surfaces of the base CS2 on the −X side, −Y side, +X side, and +Y side via the fitting structures. The +Z side opening of the base CS2 is covered with the cover CS1. The −Z side opening of the cover CS1 is covered with the base CS2. Thus, the case CS of the host HS is configured.

With this configuration, as illustrated in FIG. 22C, an information processing system SYS, in which the semiconductor storage device 1n is accommodated in the case CS of the host HS, is configured. In the information processing system SYS, the structure 10 is accommodated in the case CS of the host HS with the connector portion 4d of the perforated substrate 4 attached to the socket SC of the motherboard MB. The case CS of the host HS may be configured to have a box shape.

As described above, in the fourth embodiment, in the semiconductor storage device 1n, the structure 10, in which the connector portion 4d is provided on the outer edge of the perforated substrate 4 and the memory device 2 is mounted on the base substrate 5 through the perforated substrate 4, is configured according to the second form factor standard, for example. With this configuration, the memory device 2 can be mounted compactly, and the structure 10 including the memory device 2 can be accommodated in the space between the motherboard MB and the cover CS1 of the host HS.

### Fifth Embodiment

Next, a semiconductor storage device 1p according to a fifth embodiment will be explained. In the following, description will be mainly made on portions that are different from the first to fourth embodiments.

Although the first to third embodiments illustrate the configuration according to the first form factor standard and the fourth embodiment illustrates the configuration according to the second form factor standard, the fifth embodiment illustrates a configuration according to a third form factor standard.

The third form factor standard is a form factor standard corresponding to a flash drive, and may be the USB Type-A standard, USB Mini-A standard, USB Mini-B standard, USB Micro-A standard, USB Micro-B standard, and USB Type-C standard.

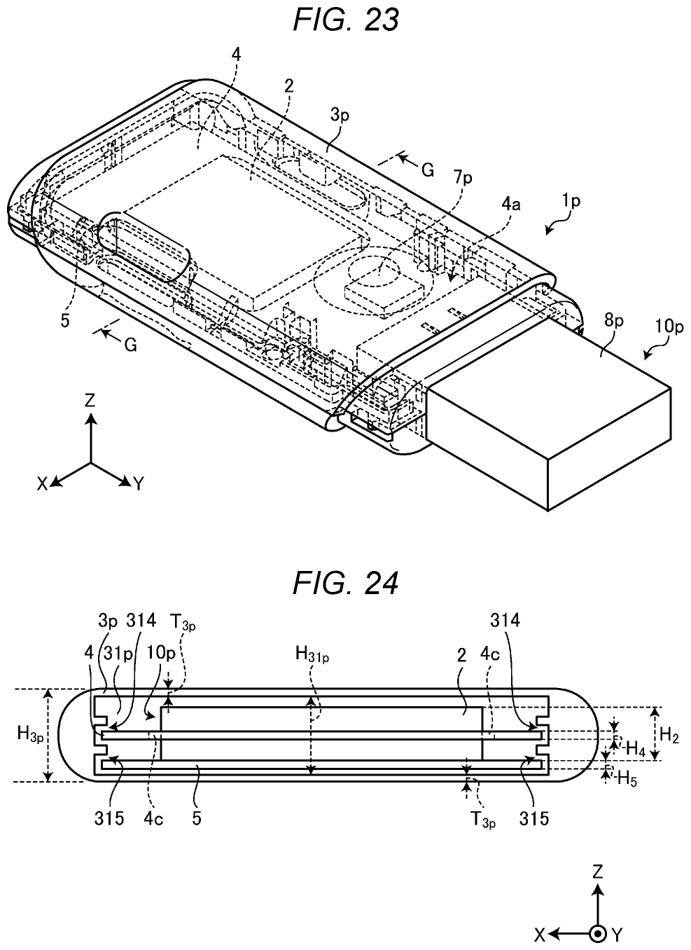

The semiconductor storage device 1p may be configured as illustrated in FIG. 23 according to the third form factor standard. FIG. 23 is a perspective view illustrating a configuration of the semiconductor storage device 1p. The semiconductor storage device 1p includes a casing 3p instead of the casing 3 (see FIG. 1), and further includes a conversion circuit chip 7p and a connector 8p. The conversion circuit chip 7p and the connector 8p are added to the structure 10 (see FIG. 4) to configure a structure 10p.

The conversion circuit chip 7p is disposed on the main surface 4a of the perforated substrate 4, connected to the memory device 2 via the electrodes 52 (see FIG. 6), wirings in the base substrate 5, and the electrodes 51 (see FIG. 6), and connected to the electrodes 41 of the connector portion 4d via wirings in the perforated substrate 4. The conversion circuit chip 7p converts a signal from the memory device 2 into a signal for the connector 8p and supplies the signal to the connector portion 4d.

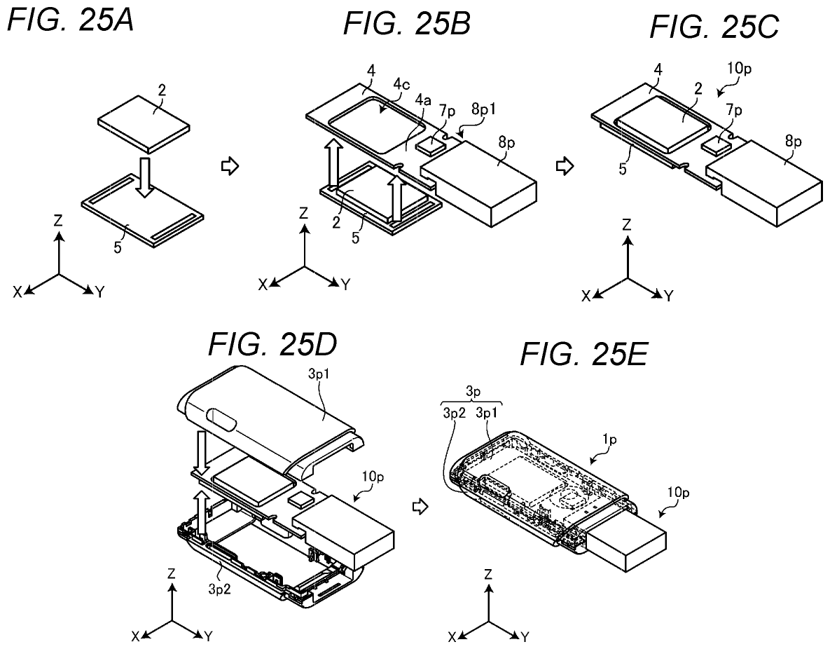

The connector 8p is disposed on the +Y side of the perforated substrate 4 and connected to the connector portion 4d. The connector 8p includes a first connector portion 8p1 corresponding to the connector portion 4d on the −Y side (see FIG. 25B), and a second connector portion (not illustrated) that supports the third form factor standard on the +Y side. The connector 8p may be regarded as a conversion component that converts a structure of the first connector portion 8p1 corresponding to the connector portion 4d into a structure of the second connector portion that supports the third form factor standard.

In the third form factor standard, the casing 3p illustrated in FIG. 24 is restricted such that a height H₃ₚ in the Z direction of the casing 3p becomes a predetermined height Hₜₕₚ or less. FIG. 24 is a cross-sectional view illustrating the configuration of the semiconductor storage device 1p, and illustrates a cross section taken along line G-G of FIG. 23. In this case, the casing 3p is configured such that the height H₃ₚ in the Z direction of the casing 3p satisfies Equation 16 below.

H₃ₚ≤Hₜₕₚ Equation 16

The casing 3p has a predetermined thickness T₃ₚ between an outer surface of the casing 3p and an inner surface of an internal space 31p. A height H₃₁ₚ in the Z direction of the internal space 31p of the casing 3p satisfies the following Equation 17.

H₃₁ₚ=H₃ₚ−2×T₃ₚ≤Hₜₕₚ−2×T₃ₚ Equation 17

In the structure 10p, a sum of the thickness H₅ of the base substrate 5, the thickness H₄ of the perforated substrate 4, and the thickness H₂ of the memory device 2 may be larger than the height H₃₁ₚ in the Z direction of the internal space 31p, as shown in FIG. 24 and the following Equation 18. For example, when the thickness H₂ of the memory device 2 is larger than the thickness H₄ of the perforated substrate 4, the tendency shown in Equation 18 becomes remarkable.

H₂+H₄+H₅>H₃₁ₚ Equation 18

When the height H₃ₚ in the Z direction of the casing 3p is equal to the predetermined height Hₜₕₚ, the following Equation 19 is established.

H₂+H₄+H₅>Hₜₕₚ Equation 19

In contrast, since the memory device 2 is mounted on the base substrate 5 through the perforated substrate 4, a height of the structure 10p is just a sum of the thickness H₅ of the base substrate 5 and the thickness H₂ of the memory device 2. For example, even when the thickness H₂ of the memory device 2 is larger than the thickness H₄ of the perforated substrate 4, since the thickness H₄ of the perforated substrate 4 is provided in the thickness H₂ of the memory device 2, the height of the structure 10p is just the sum of the thickness H₅ of the base substrate 5 and the thickness H₂ of the memory device 2. The sum of the thickness H₅ of the base substrate 5 and the thickness H₂ of the memory device 2 can be smaller than the height H₃₁ₚ in the Z direction of the internal space 31p, as shown in FIG. 24 and the following Equation 20.

H₂+H₅<H₃₁ₚ Equation 20

When the height H₃ₚ in the Z direction of the casing 3p is equal to the predetermined height Hₜₕₚ, an expression H₃₁ₚ=H₃ₚ−2×T₃ₚ=Hₜₕₚ−2×T₃ₚ holds, and thus, when substituting this formula into Equation 20, the following Equation 20′ is established.

H₂+H₅<Hₜₕₚ−2×T₃ₚ Equation 20′

As shown in Equations 20 and 20′, the structure 10p may be accommodated in the internal space 31p of the casing 3p by mounting the memory device 2 on the base substrate 5 through the perforated substrate 4. The structure 10p may also be equivalently regarded as a structure in which the memory device 2 is mounted beyond the predetermined height Hₜₕₚ restriction (see Equation 19) of the third form factor standard.

As illustrated in FIGS. 25A to 25E, a method for manufacturing the semiconductor storage device 1p differs from the first to fourth embodiments in the following points. FIGS. 25A to 25E are perspective views illustrating the method for manufacturing the semiconductor storage device 1p.

In a step illustrated in FIG. 25A, the memory device 2 is mounted on the main surface 5a of the base substrate 5. The memory device 2 is mounted on the main surface 5a by bonding the plurality of external electrodes 25 (see FIG. 6) to the plurality of electrodes 51 (see FIG. 5). The bonding may be alloy bonding by heating each electrode, or may be solder bonding in which the bonding is made by heating and melting solder between the electrodes.

In a step illustrated in FIG. 25B, the perforated substrate 4 is disposed on the +Z side of the structure in which the memory device 2 is mounted on the base substrate 5. The conversion circuit chip 7p is mounted on the main surface 4a of the perforated substrate 4 on the +Z side. Although not illustrated, a plurality of electrodes may be disposed on the main surface 4a of the perforated substrate 4 on the +Z side, a plurality of electrodes may be disposed on a main surface of the conversion circuit chip 7p on the −Z side, and the plurality of electrodes of the conversion circuit chip 7p may be bonded to the plurality of electrodes of the main surface 4a of the perforated substrate 4.

The connector portion 4d of the perforated substrate 4 is attached so as to be inserted into the first connector portion 8p1 of the connector 8p.

The perforated substrate 4 is aligned so that the hollow portion 4c is at the XY position corresponding to the memory device 2, and the connector portion 4d is on the +Y side. The perforated substrate 4 is brought closer to the base substrate 5 in the Z direction, and the perforated substrate 4 is mounted on the main surface 5a of the base substrate 5. The perforated substrate 4 is mounted on the main surface 5a outside the memory device 2 by bonding the plurality of electrodes 42 (see FIG. 6) to the plurality of electrodes 52 via the plurality of conductors 45. The bonding may be alloy bonding by heating each electrode, or may be solder bonding in which the bonding is made by heating and melting solder between the electrodes.

With this configuration, the structure 10p illustrated in FIG. 25C is obtained. In the structure 10p, the memory device 2 is mounted on the base substrate 5 through the perforated substrate 4.

In a step illustrated in FIG. 25D, fitting structures are provided on the −Z side end portions of side surfaces of the cover 3p1 on the −X side, −Y side, and +X side and the +Z side end portions of side surfaces of the base 3p2 on the −X side, −Y side, and +X side, respectively. The side surfaces of the cover 3p1 on the −X side, −Y side, and +X side are coupled to the side surfaces of the base 3p2 on the −X side, −Y side, and +X side via the fitting structures. The +Z side opening of the base 3p2 is covered with the cover 3p1. The −Z side opening of the cover 3p1 is covered with the base 3p2. Thus, the casing 3p is configured.

Thus, the semiconductor storage device 1p illustrated in FIG. 25E is obtained. In the semiconductor storage device 1p, the structure 10p is accommodated in the internal space 31p of the casing 3p.

As described above, in the fifth embodiment, in the semiconductor storage device 1p, the structure 10p, in which the connector portion 4d is provided on the outer edge of the perforated substrate 4 and the memory device 2 is mounted on the base substrate 5 through the perforated substrate 4, is configured according to the third form factor standard, for example. With this configuration, the memory device 2 can be compactly mounted, and the structure 10p including the memory device 2 can be accommodated in the casing 3p.

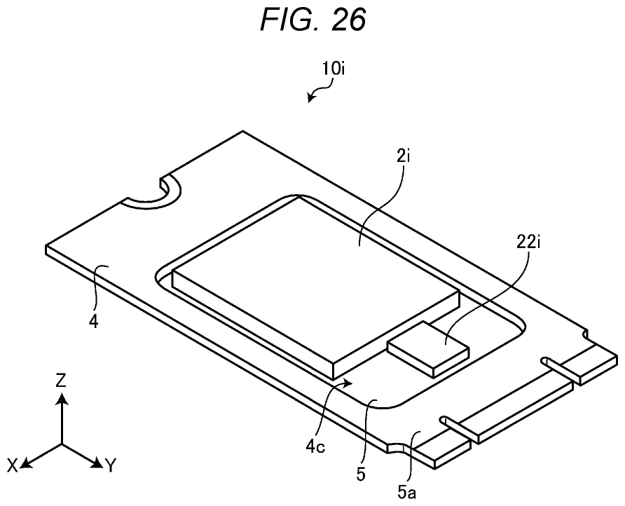

Further, as a modification of the first to fifth embodiments, as illustrated in FIG. 26, in a structure 10i, in addition to a memory device 2i, other components may be disposed in the hollow portion 4c of the perforated substrate 4. For example, a controller chip 22i for controlling the plurality of memory chips 21 (see FIG. 6) in the memory device 2i may be disposed outside the memory device 2i instead of being provided in the memory device 2i. FIG. 26 is a perspective view illustrating a configuration of the structure 10i in the modification of the first to fifth embodiments. The controller chip 22i is disposed on the main surface 5a of the base substrate 5 at a position adjacent to the memory device 2i in the XY direction. The controller chip 22i is disposed in the hollow portion 4c of the perforated substrate 4 at a position adjacent to the memory device 2i in the XY direction.

Also in this structure 10i, since a height of the structure 10i is just a sum of the thickness H₅ of the base substrate 5 and the thickness H₂ of the memory device 2i, the memory device 2i can be compactly mounted, and the structure 10i including the memory device 2i can be accommodated in the casing 3 (see FIG. 3).

Further, for example, the controller chip 22 and the spacer 26 (see FIG. 6) are reduced in the memory device 2i, and the number of memory chips 21 corresponding to the height in the Z direction of the reduced controller chip 22 and spacer 26 may be additionally stacked. With this configuration, the memory capacity of the memory device 2i can be increased while maintaining the thickness of the memory device 2i at H₂.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a memory device including a memory chip;
a first substrate having a first main surface and a second main surface, the memory device disposed on the first main surface, the second main surface disposed on a side opposite to the first main surface; and
a second substrate having a third main surface and a fourth main surface, the third main surface facing the first main surface, the fourth main surface disposed on a side opposite to the third main surface, and having a hollow portion penetrating from the third main surface to the fourth main surface and a connector portion is disposed on an outer edge, wherein
the memory device is disposed within the hollow portion.

2. The semiconductor storage device according to claim 1, further comprising:
a casing having a box shape having an opening at a side end, wherein
the memory device, the first substrate, and the second substrate are accommodated in an internal space of the casing.

3. The semiconductor storage device according to claim 2, further comprising:
a socket, the memory device being attached to the socket, and the socket disposed on the first main surface and disposed in the hollow portion.

4. The semiconductor storage device according to claim 1, wherein
the connector portion supports a predetermined form factor standard.

5. The semiconductor storage device according to claim 2, wherein
a sum of a thickness of the first substrate, a thickness of the second substrate, and a thickness of the memory device is larger than a height of the internal space, and
a sum of the thickness of the first substrate and the thickness of the memory device is smaller than the height of the internal space.

6. The semiconductor storage device according to claim 3, wherein
a sum of a thickness of the first substrate, a thickness of the second substrate, and a height of the socket is larger than a height of the internal space, and
a sum of the thickness of the first substrate and the height of the socket is smaller than the height of the internal space.

7. The semiconductor storage device according to claim 4, wherein
a sum of a thickness of the first substrate and a thickness of the memory device is less than or equal to a predetermined height prescribed by the predetermined form factor standard.

8. The semiconductor storage device according to claim 2, wherein
a thickness of the memory device is larger than a thickness of the second substrate.

9. The semiconductor storage device according to claim 3, wherein
a height of the socket is larger than a thickness of the second substrate.

10. The semiconductor storage device according to claim 2, wherein
the connector portion is positioned near a center in a height direction in the internal space.

11. The semiconductor storage device according to claim 1, wherein
a dimension in a longitudinal direction of the second substrate is larger than a dimension in a longitudinal direction of the first substrate.

12. The semiconductor storage device according to claim 1, wherein
the connector portion is disposed at an edge portion in a longitudinal direction of the second substrate.

13. The semiconductor storage device according to claim 1, wherein
the memory device includes a plurality of memory chips, and the plurality of memory chips are stacked.

14. The semiconductor storage device according to claim 1, wherein
the memory chip includes a stacked body in which a plurality of conductive layers are stacked via insulating layers, and semiconductor pillars,
in the memory chip, a three-dimensional memory is configured by penetrating the stacked body in a stacking direction with the semiconductor pillars and with insulating films covering side surfaces of the semiconductor pillars, and
in the three-dimensional memory, memory cells formed at portions where the conductive layers and the semiconductor pillars intersect are located three-dimensionally.

15. The semiconductor storage device according to claim 1, wherein
the memory device further includes a controller chip configured to control the memory chip.

16. The semiconductor storage device according to claim 1, further comprising:
a controller chip disposed on the first main surface of the first substrate at a position adjacent to the memory device and disposed in the hollow portion of the second substrate.

17. An information processing system comprising:
a semiconductor storage device; and
a host including: (i) a case and (ii) a board accommodated in the case and attached to the semiconductor storage device, wherein
the semiconductor storage device includes:
a memory device including a memory chip,
a first substrate having a first main surface and a second main surface, the memory device disposed on the first main surface, the second main surface on a side opposite to the first main surface, and
a second substrate having a third main surface and a fourth main surface, the third main surface facing the first main surface, the fourth main surface being on a side opposite to the third main surface, and having a hollow portion penetrating from the third main surface to the fourth main surface and a connector portion disposed on an outer edge, wherein
the memory device is disposed inside the hollow portion.

18. The information processing system according to claim 17, wherein
the case includes a base and a cover, and
a sum of a thickness of the first substrate and a thickness of the memory device is smaller than a gap between the cover and the board.

19. The semiconductor storage device according to claim 1, wherein the semiconductor storage device includes a solid state drive.

20. The semiconductor storage device according to claim 1, wherein the memory chip includes a NAND flash memory chip.
